(19) United States
(12) Patent Application Publication
(10) Pub. No.: US 2007/0235805 A1
(43) Pub. Date: Oct. 11, 2007

(54) TFT array substrate and method for manufacturing same

(75) Inventor: Shuo-Ting Yan, Miao-Li (TW)

Correspondence Address: WEI TE CHUNG;FOXCONN INTERNATIONAL, INC., 1650 MEMOREX DRIVE, SANTA CLARA, CA, 95050, US

(73) Assignee: INNOLUX DISPLAY CORP.

(21) Appl. No.: 11/784,865

(22) Filed: Apr. 9, 2007

(30) Foreign Application Priority Data
Apr. 7, 2006 (TW) 95112469

(51) Int. Cl. H01L 27/12

(52) U.S. Cl. 257/347

(57) ABSTRACT

An exemplary TFT array substrate (200) includes a glass substrate (201); a source electrode (215), a channel (212), and a drain electrode (216) formed on the substrate, the channel being between the source electrode and the drain electrode; a gate insulating layer (203) formed on the channel; a gate electrode (214) formed on the gate insulating layer, and corresponding to the channel; and a passivation layer (206) formed on the source electrode, the drain electrode, the passivation layer having a dielectric constant less than that of the gate insulating layer. A width of the gate insulating layer is less than a corresponding width of each of the gate electrode and the channel, and portions of the passivation layer are located adjacent the gate insulating layer between the gate electrode and the channel.

### FIELD OF THE INVENTION

This invention relates to a thin film transistor (TFT) array substrate of a TFT liquid crystal display (LCD), and more particularly to a TFT array substrate with a small leakage current and high reliability. The invention also relates to a method for manufacturing the TFT array substrate.

### GENERAL BACKGROUND

A TFT LCD has the advantages of portability, low power consumption, and low radiation, and has been widely used in various portable information products such as notebooks, personal digital assistants (PDAs), video cameras and the like. Furthermore, the TFT LCD is considered by many to have the potential to completely replace CRT (cathode ray tube) monitors and televisions.

In general, a TFT LCD includes a TFT array substrate. A typical TFT array substrate mainly includes a plurality of gate lines arranged in parallel and each extending along a first direction, and a plurality of data lines arranged in parallel and each extending along a second direction perpendicular to that of the gate lines. Thus, the gate lines and data lines define a multiplicity of pixel regions arranged in an array. Each pixel region has a TFT provided thereat. In operation, column data lines simultaneously apply required voltages to every pixel region in a row of pixel regions as selected by row gate lines. Some of the required voltages turn on the respective TFTs of the pixel regions in that row, to charge the corresponding storage capacitors of those pixel regions. Once each TFT is turned off, the storage capacitor of that TFT holds the pixel region at the set voltage level until a next refresh cycle.

FIG. 11 is a schematic, side cross-sectional view of part of a conventional TFT array substrate. The TFT array substrate 100 includes: a glass substrate 101; a channel 113, a source electrode 114, and a drain electrode 115 formed on the substrate 101; a gate insulating layer 104 formed on the channel 113, the source electrode 114, and the drain electrode 115; a gate electrode 105 formed on the gate insulating layer 104 and corresponding to the channel 113; a passivation layer 106 formed on the gate electrode 105 and the gate insulating layer 104; three contact holes (not labeled) selectively formed in the passivation layer 106 and the gate insulating layer 104; and a patterned metal layer 107 formed on the passivation layer 106 including in the contact holes. The gate insulating layer 104 is made of SiOₓ material (such as SiO₂), which is a standard material and has a dielectric constant of 3.9.

FIG. 12 is a flow chart of a typical method for manufacturing the TFT array substrate 100. The method includes the following steps, which are described in relation to what is shown in FIG. 11: providing a glass substrate 101 (step S10); forming a channel 113, a source electrode 114, and a drain electrode 115 on the glass substrate 101 (step S11); forming a gate insulating layer 104 on the channel 113, the source electrode 114, and the drain electrode 115 (step S12); forming a gate electrode 105 on the gate insulating layer 104 (step S13); forming a passivation layer 106 and three contact holes on the gate insulating layer 104 and the gate electrode 105 (S14); and forming a patterned metal layer 107 (S15), parts of which are in ohmic contact with the gate electrode 105, the source electrode 114, and the drain electrode 115 via the contact holes respectively.

Thus, the TFT array substrate 100 as described above is obtained. However, the gate insulating layer 104 that is formed between the gate electrode 105 and the channel 113 is made of SiOₓ material, which typically has a dielectric constant of 3.9. That is, the gate insulating layer 104 taken as a dielectric layer has limited insulative capability. This means leakage current is liable to be generated between the source electrode 114 and the drain electrode 115. The leakage current is liable to disturb voltage signals which generate electric fields that drive liquid crystal molecules of the TFT LCD to rotate. That is, the liquid crystal molecules may be incorrectly or inaccurately driven, and the TFT array substrate 100 may not be able to reliably provide good quality images for the corresponding TFT LCD.

What is needed, therefore, is a TFT array substrate of a TFT LCD and a method for manufacturing the TFT array substrate that can overcome the above-described deficiencies.

### SUMMARY

An exemplary TFT array substrate includes: a glass substrate; a source electrode, a channel, and a drain electrode formed on the substrate, the channel being between the source electrode and the drain electrode; a gate insulating layer formed on the channel; a gate electrode formed on the gate insulating layer and corresponding to the channel; and a passivation layer formed including on the source electrode and the drain electrode, the passivation layer having a dielectric constant less than that of the gate insulating layer. A width of the gate insulating layer is less than a corresponding width of each of the gate electrode and the channel, and portions of the passivation layer are located adjacent the gate insulating layer between the gate electrode and the channel.

A method for manufacturing the TFT array substrate is also provided. The method includes the steps of: providing a glass substrate, and forming a semiconductor layer on the glass substrate; depositing an SiOₓ layer on the semiconductor layer to form a gate insulating layer; forming a patterned gate electrode on the gate insulating layer; wet etching the gate insulating layer by using the gate electrode pattern as a mask, whereby a width of the gate insulating layer at each gate electrode is less than a corresponding width of the gate electrode; introducing n-type impurities into portions of the semiconductor layer by using the gate electrode pattern as a mask, thereby forming a plurality of source electrodes, a plurality of drain electrodes, and a plurality of channels, each of the channels located below a corresponding one of the gate electrodes between a corresponding one of the source electrodes and a corresponding one of the drain electrodes; and depositing a passivation layer on the gate electrodes, the source electrodes, and the drain electrodes, portions of the passivation layer filling gaps between each of the gate electrodes and the corresponding channel, the passivation layer having a dielectric constant less than that of the gate insulating layer.

Other novel features and advantages will become more apparent from the following detailed description when taken in conjunction with the accompanying drawings.

### BRIEF DESCRIPTION OF THE DRAWINGS

FIG. 1 is a schematic, side cross-sectional view of part of a TFT array substrate according to an exemplary embodiment of the present invention.

FIG. 2 is a flow chart of an exemplary method for manufacturing the TFT array substrate of FIG. 1.

FIGS. 3-10 are schematic, side cross-sectional views of successive precursors of the part of the TFT array substrate shown in FIG. 1, each view relating to a corresponding one of manufacturing steps of the method of FIG. 2.

FIG. 11 is a schematic, side cross-sectional view of part of a conventional TFT array substrate.

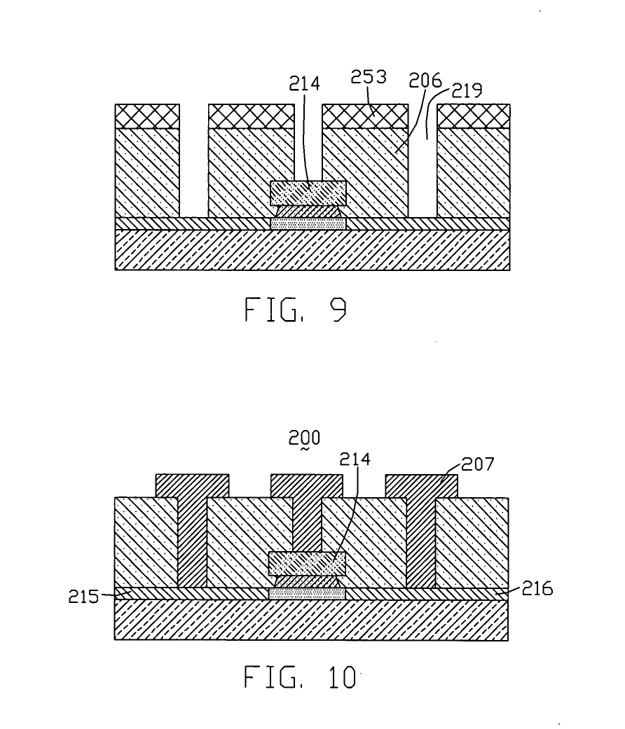

FIG. 12 is a flow chart of a conventional method for manufacturing the TFT array substrate of FIG. 11.

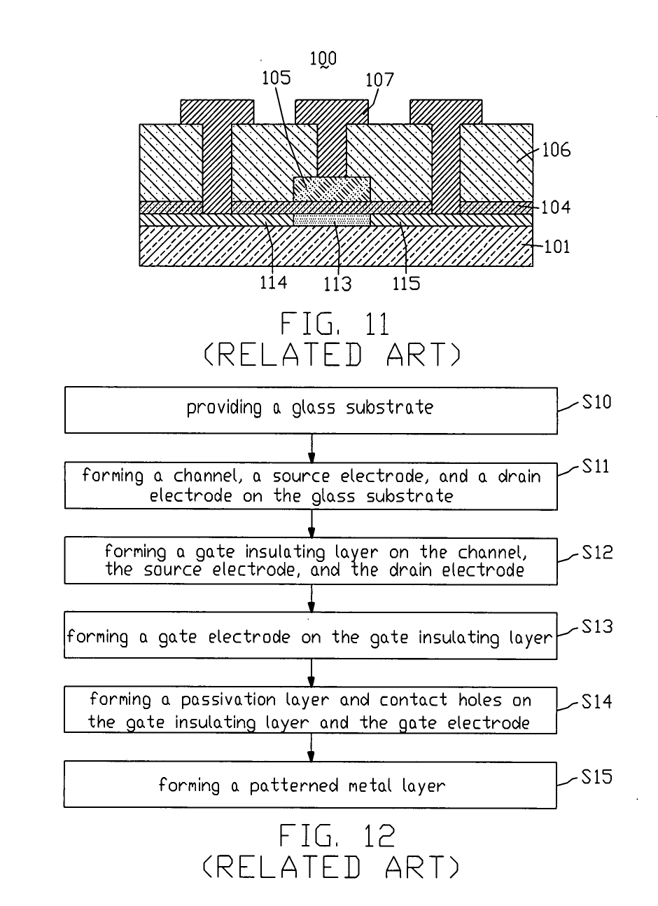

### DETAILED DESCRIPTION OF PREFERRED EMBODIMENTS

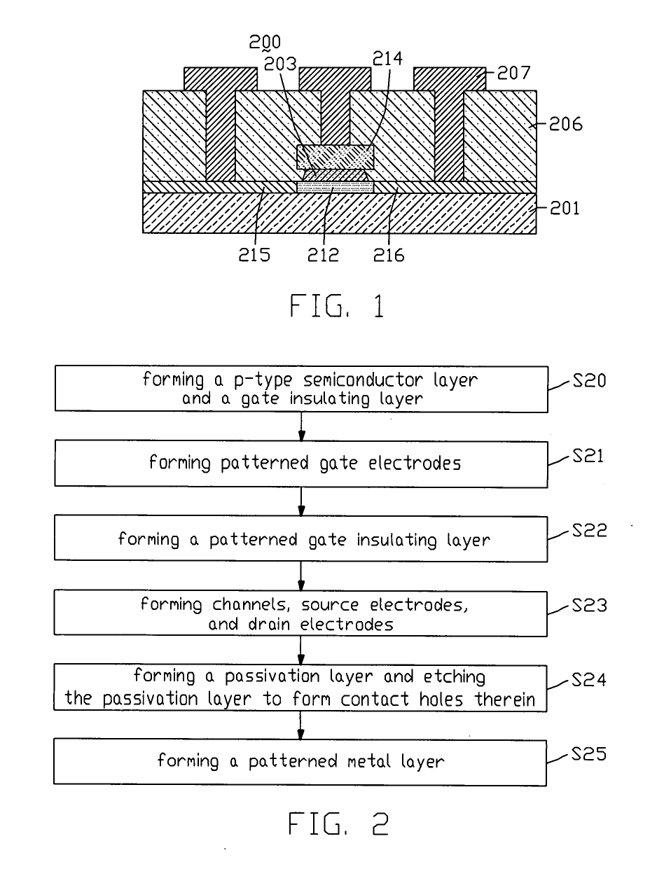

Referring to FIG. 1, a schematic, side cross-sectional view of part of a TFT array substrate according to an exemplary embodiment of the present invention is shown. The TFT array substrate 200 includes: a base substrate 201; a channel 212, a source electrode 215, and a drain electrode 216 formed on the substrate 201; a gate insulating layer 203 formed on the channel 212; a gate electrode 214 formed on the gate insulating layer 203 and corresponding to the channel 212; a passivation layer 206 formed on the gate electrode 214, the source electrode 215, the drain electrode 216, and the channel 212; and a patterned metal layer 207 formed on the passivation layer 206. Three contact holes (not labeled) are formed in the passivation layer 206; and parts of the patterned metal layer 207 are in ohmic contact with the gate electrode 214, the source electrode 215, and the drain electrode 216 via the contact holes respectively. In the illustrated embodiment, a width of the gate insulating layer 203 is less than a corresponding width of each of the gate electrode 214 and the channel 212, and portions of the passivation layer 206 are located adjacent the gate insulating layer 203 between the gate electrode 214 and the channel 212.

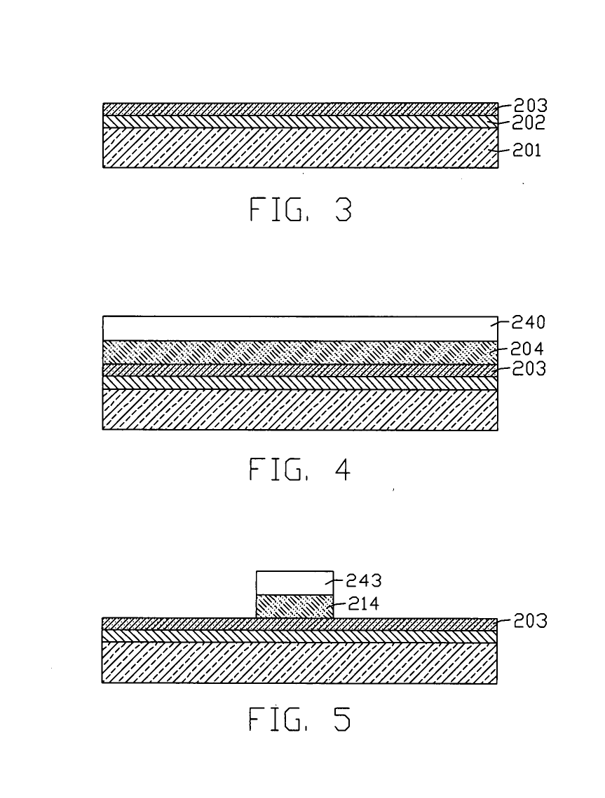

Also referring to FIG. 2, a flow chart of an exemplary method for manufacturing the TFT array substrate 200 is shown. The manufacturing steps are described in detail below in relation to what is shown in FIG. 1, which essentially pertains to one pixel unit of the TFT array substrate 200.

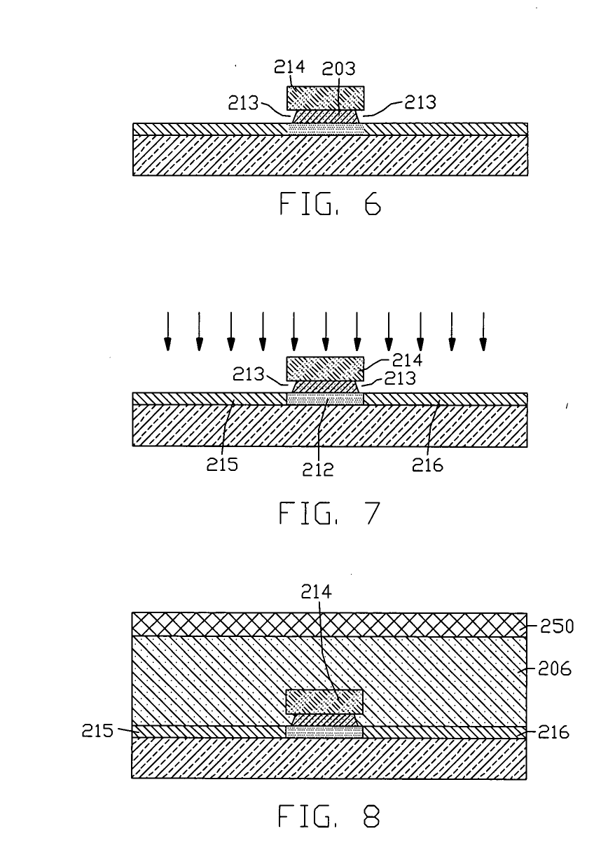

In step S20, a p-type semiconductor layer and a gate insulating layer are formed. Referring to FIG. 3, this includes providing a glass substrate 201, and depositing an amorphous silicon layer on the glass substrate 201. Then the amorphous silicon layer is crystallized by a laser annealing process or a rapid thermal annealing process to form a polycrystalline silicon layer, and p-type impurities such as boron ions are introduced into the polycrystalline silicon layer to form a p-type semiconductor layer 202. After that, SiOₓ material is deposited on the p-type semiconductor layer 202 to form a gate insulating layer 203. The SiOₓ material has a dielectric constant of 3.9, and can for example be SiO₂.

In step S21, a patterned plurality of gate electrodes is formed. Referring to FIG. 4, this includes depositing a gate electrode metal layer 204 and a first resist layer 240 in that order on the gate insulating layer 203. Then the first resist layer 240 is exposed and developed via a first patterned mask, so as to form a patterned resist layer 243. After that, the gate electrode metal layer 204 is dry etched to form a patterned plurality of gate electrodes 214 (only one gate electrode 214 is shown in FIG. 5).

In step S22, a patterned gate insulating layer is formed. Referring to FIG. 6, this includes removing the patterned resist layer 243, and wet etching the gate insulating layer 203 by using the gate electrode 214 as a mask. Because wet etching is an isotropic type of etching process, the gate insulating layer 203 is downwardly etched and side etched during the etching process. This causes two end portions of the gate insulating layer 203 under the gate electrode 214 to be etched, so as to form two opposite gaps 213 thereat.

In step S23, a plurality of channels, a plurality of source electrodes, and a plurality of drain electrodes are formed. Referring to FIG. 7, this typically includes heavily introducing n-type impurities such as phosphorus ions into portions of the p-type semiconductor layer 202 not covered by the gate electrode 214, wherein the gate electrode 214 functions as a mask. Thereby, a source electrode 215 and a drain electrode 216 are formed at each pixel unit. The portion of the p-type semiconductor layer 202 covered by the gate electrode 214 forms a channel 212 of the pixel unit.

In step S24, a passivation layer is formed, and the passivation layer is etched to form contact holes therein. Referring to FIG. 8, a passivtion layer 206 is formed on the source electrode 215, the drain electrode 216, and the gate electrode 214 via a spinning process. The passivation layer 206 also fills the gaps 213 under the gate electrode 214. Then, a second resist layer 250 is deposited on the passivation layer 206. Referring also to FIG. 9, the second resist layer 250 is exposed and developed via a second patterned mask, so as to form a patterned resist layer 253. After that, the passivation layer 206 is dry etched to form three contact holes 219 therein (as shown in FIG. 9). The passivation layer 206 is made of a material having a dielectric constant less than that of the gate insulating layer 203. That is, the passivation layer 206 has a dielectric constant less than 3.9. For example, the passivation layer 206 can be made of hydrogen silsesquioxane (HSQ).

In step S25, a patterned metal layer is formed. Referring to FIG. 10, this can include depositing a patterned metal layer 207 on the passivation layer 206 and in the three contact holes 219. Parts of the metal layer 207 are in ohmic contact with the gate electrode 214, the source electrode 215, and the drain electrode 216 via the contact holes 219, respectively.

Thus, a plurality of pixel units of the above-described TFT array substrate 200 of a TFT LCD is obtained. FIG. 10 shows one such pixel unit.

With this structure, the two opposite ends of the gate insulating layer 203 are abutted by material having a lower dielectric constant than that of the gate insulating layer 203 itself. That is, the two ends of the gate insulating layer 203 (having a dielectric constant of 3.9) are abutted by the passivation layer 206 (having a dielectric constant of <3.9). The lower dielectric constant material has a larger bias voltage. That is, two opposite ends of the channel 212 corresponding to the two ends of the gate insulating layer 203 have a lower voltage coupling and a weaker electric field. Therefore, generation of a leakage current between the source electrode 215 and the drain electrode 216 is avoided. When there is little or no leakage current, voltage signals which generate electric fields that drive liquid crystal molecules of a corresponding TFT LCD to rotate are apt to not be disturbed. That is, the liquid crystal molecules can be properly driven, which helps ensure that the TFT array substrate 200 can reliably provide good quality images for the TFT LCD. Moreover, the lower dielectric constant material of the passivation layer 206 can also reduce any crosstalk between the gate electrode 214 and the patterned metal layer 207. This can further improve the reliability of the TFT array substrate 200.

In alternative embodiments, the passivation layer 206 may instead be made of methylsilsesquioxane (MSQ), porous-polysilazane (PPSZ), benzocyclobutene (BCB), fluorinated arylene ether (FLARE), polynuclear aromatic hydrocarbons (PAHs), black diamond, hybrid organic siloxanepolymer (HOSP), polyarylene ether (PAE), diamond-like carbon (DLC), or any other suitable material having a low dielectric constant.

It is to be further understood that even though numerous characteristics and advantages of the present embodiments have been set out in the foregoing description, together with details of structures and functions of the embodiments, the disclosure is illustrative only, and changes may be made in detail, including in matters of shape, size, and arrangement of parts within the principles of the invention to the full extent indicated by the broad general meaning of the terms in which the appended claims are expressed.

What is claimed is:

1. A thin film transistor array substrate, comprising:
a glass substrate;
a source electrode, a channel, and a drain electrode formed on the substrate, the channel being between the source electrode and the drain electrode;
a gate insulating layer formed on the channel;
a gate electrode formed on the gate insulating layer, and corresponding to the channel; and
a passivation layer formed including on the source electrode and the drain electrode, the passivation layer having a dielectric constant less than that of the gate insulating layer;
wherein a width of the gate insulating layer is less than a corresponding width of each of the gate electrode and the channel, and portions of the passivation layer are located adjacent the gate insulating layer between the gate electrode and the channel.

2. The thin film transistor array substrate as claimed in claim 1, wherein the gate insulating layer is made of SiOₓ material.

3. The thin film transistor array substrate as claimed in claim 2, wherein the SiOₓ material is SiO₂ material.

4. The thin film transistor array substrate as claimed in claim 2, wherein the passivation layer is made of material selected from the group consisting of methylsilsesquioxane (MSQ), porous-polysilazane (PPSZ), benzocyclobutene (BCB), fluorinated arylene ether (FLARE), polynuclear aromatic hydrocarbons (PAHs), black diamond, hybrid organic siloxanepolymer (HOSP), polyarylene ether (PAE), and diamond-like carbon (DLC).

5. The thin film transistor array substrate as claimed in claim 1, wherein the passivation layer is also formed on the gate electrode.

6. The thin film transistor array substrate as claimed in claim 5, wherein the passivation layer comprises a plurality of contact holes therein.

7. The thin film transistor array substrate as claimed in claim 6, further comprising a patterned metal layer formed on the passivation layer including in the contact holes, wherein portions of the patterned metal layer are in ohmic contact with the gate electrode, the source electrode, and the drain electrode via the contact holes, respectively.

8. A method for manufacturing a thin film transistor array substrate, comprising:
providing a glass substrate, and forming a semiconductor layer on the glass substrate;
depositing an SiOₓ layer on the semiconductor layer to form a gate insulating layer;
forming patterned gate electrodes on the gate insulating layer;
wet etching the gate insulating layer by using the gate electrode pattern as a mask, whereby a width of the gate insulating layer at each gate electrode is less than a corresponding width of the gate electrode;
introducing n-type impurities into portions of the semiconductor layer by using the gate electrode pattern as a mask, thereby forming a plurality of source electrodes, a plurality of drain electrodes, and a plurality of channels, each of the channels located below a corresponding one of the gate electrodes between a corresponding one of the source electrodes and a corresponding one of the drain electrodes; and
depositing a passivation layer on the gate electrodes, the source electrodes, and the drain electrodes, portions of the passivation layer filling gaps between each of the gate electrodes and the corresponding channel, the passivation layer having a dielectric constant less than that of the gate insulating layer.

9. The method as claimed in claim 8, wherein the gate insulating layer is made of SiO₂ material.

10. The method as claimed in claim 8, wherein the passivation layer is made of material of selected from the group consisting of methylsilsesquioxane (MSQ), porous-polysilazane (PPSZ), benzocyclobutene (BCB), fluorinated arylene ether (FLARE), polynuclear aromatic hydrocarbons (PAHs), black diamond, hybrid organic siloxanepolymer (HOSP), polyarylene ether (PAE), and diamond-like carbon (DLC).

11. The method as claimed in claim 8, further comprising forming a plurality of contact holes in the passivation layer.

12. The method as claimed in claim 11, wherein the contact holes are formed by a dry etching process.

13. The method as claimed in claim 10, further comprising forming a patterned metal layer on the passivation layer.

14. The method as claimed in claim 13, wherein the patterned metal layer is in ohmic contact with each of the gate electrodes, each of the source electrodes, and each of the drain electrodes via the contact holes, respectively.
